(19) United States
(12) Patent Application Publication
(10) Pub. No.: US 2015/0171279 A1
(43) Pub. Date: Jun. 18, 2015

(54) EPITAXIAL SUBSTRATE, METHOD THEREOF, AND LIGHT EMITTING DIODE

(71) Applicant: Hwasun Quartek Corporation, Zhongli City (TW)

(72) Inventors: Chih-Yuan LEE, Taoyuan City (TW); Kuo-Hsiung CHANG, Daxi Township (TW); Chung-Wei LI, Zhongli City (TW); Sin-Chun LI, Zhongli City (TW)

(21) Appl. No.: 14/468,001

(22) Filed: Aug. 25, 2014

(30) Foreign Application Priority Data
Dec. 12, 2013 (TW) 102145929

(51) Int. Cl. H01L 33/48

(52) U.S. Cl. CPC H01L 33/48

(57) ABSTRACT

An epitaxial substrate includes a main body having a surface and a plurality of protrusions formed on the surface of the main body and spaced apart from one another. Each of the protrusions has a dimension different from at least adjacent one of the protrusions. A method for producing the epitaxial substrate and a light emitting diode including the epitaxial substrate are also disclosed.

### CROSS-REFERENCE TO RELATED APPLICATION

This application claims priority of Taiwanese Patent Application No. 102145929, filed on December 12, 2013, the entire disclosure of which is hereby incorporated by reference.

### BACKGROUND OF THE INVENTION

1. Field of the Invention This invention relates to an epitaxial substrate, more particularly to an epitaxial substrate used in a light emitting diode.

2. Description of the Related Art

Light emitting diode (LED) technology is currently one of the most important lighting technologies in the industry. Recent efforts have focused on improvement in the brightness and luminous efficacy of the light emitting diode. It is known that a patterned epitaxial substrate can be used to improve epitaxial quality and luminous efficacy of a light emitting diode.

Taiwanese Utility Model No. M420049 discloses a patterned sapphire substrate (PSS) formed with a plurality of pyramid structures (protrusion structures). The pyramid structures are the same in dimension and are equidistantly arranged on a surface of the patterned sapphire substrate. Compared to a non-patterned sapphire substrate, the patterned sapphire substrate has better luminous efficacy. However, the improvement of luminous efficacy is limited due to the same dimension of the pyramid structures.

On the other hand, the conventional patterned sapphire substrate is mainly made using photolithography technology to produce a patterned etching mask, followed by etching the sapphire substrate using the patterned etching mask to produce the patterned sapphire substrate. In general, an exposure machine or a stepper is commonly used to produce the patterned etching mask. However, the stepper is operated to form the protrusion structures on a part of the surface of the sapphire substrate and subsequently form the protrusion structures on another part of the surface of the sapphire substrate. Moreover, the stepper is unsuitable to form a patterned etching mask having various protrusion structures. The exposure machine cannot produce patterns with relatively larger dimension deviation. As such, the design of the pattern of the patterned sapphire substrate is restricted by the photolithography technology.

### SUMMARY OF THE INVENTION

Therefore, the object of the present invention is to provide an epitaxial substrate that can overcome the aforesaid drawback of the prior art.

According to one aspect of the present invention, there is provided an epitaxial substrate that includes a main body having a surface, and a plurality of protrusions formed on the surface of the main body and spaced apart from one another. Each of the protrusions has a dimension different from at least an adjacent one of the protrusions.

According to another aspect of the present invention, there is provided a method for producing the aforesaid epitaxial substrate that includes the steps of:

(a) preparing a planar epitaxial substrate that has a surface, and a mold that has a patterned surface indented to form a plurality of spaced-apart indentations;

(b) depositing a curable layer on the surface of the planar epitaxial substrate, and imprinting the curable layer with the mold so as to form a patterned curable layer formed with a plurality of projections corresponding to the indentations of the mold; and

(c) etching the planar epitaxial substrate using the patterned curable layer as a mask so as to form the epitaxial substrate having the protrusions corresponding in position to the projections of the patterned curable layer.

According to yet another aspect of the present invention, there is provided a light emitting diode that includes the aforesaid epitaxial substrate, a buffer layer, a first-type semiconductor layer, a semiconductor light emitting layer, a second-type semiconductor layer and two electrodes. The buffer layer is deposited on the main body and the protrusion of the epitaxial substrate. The first-type semiconductor layer is deposited on the buffer layer opposite to the epitaxial substrate. The semiconductor light emitting layer is deposited on the first-type semiconductor layer opposite to the buffer layer. The second-type semiconductor layer is deposited on the semiconductor light emitting layer opposite to the first-type semiconductor layer, and has an electrical property opposite to that of the first-type semiconductor layer. The two electrodes are adapted to be electrically connected an external power source and are respectively electrically connected to the first-type semiconductor layer and the second-type semiconductor layer.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a schematic view of the preferred embodiment of an epitaxial substrate according to this invention;

FIG. 2 is a schematic top view of the preferred embodiment;

FIG. 3 is an enlarged view of FIG. 2;

FIG. 4 is a schematic top view of a variation of the preferred embodiment;

FIG. 5 is a schematic top view of another variation of the preferred embodiment;

FIG. 6 is a flowchart of the preferred embodiment of a method for producing an epitaxial substrate according to this invention;

FIGS. 7(A) to 7(E) are schematic views illustrating the preferred embodiment of the method for producing the epitaxial substrate; and

FIG. 8 is a schematic view of the preferred embodiment of a light emitting diode according to this invention.

### DETAILED DESCRIPTION OF THE PREFERRED EMBODIMENTS

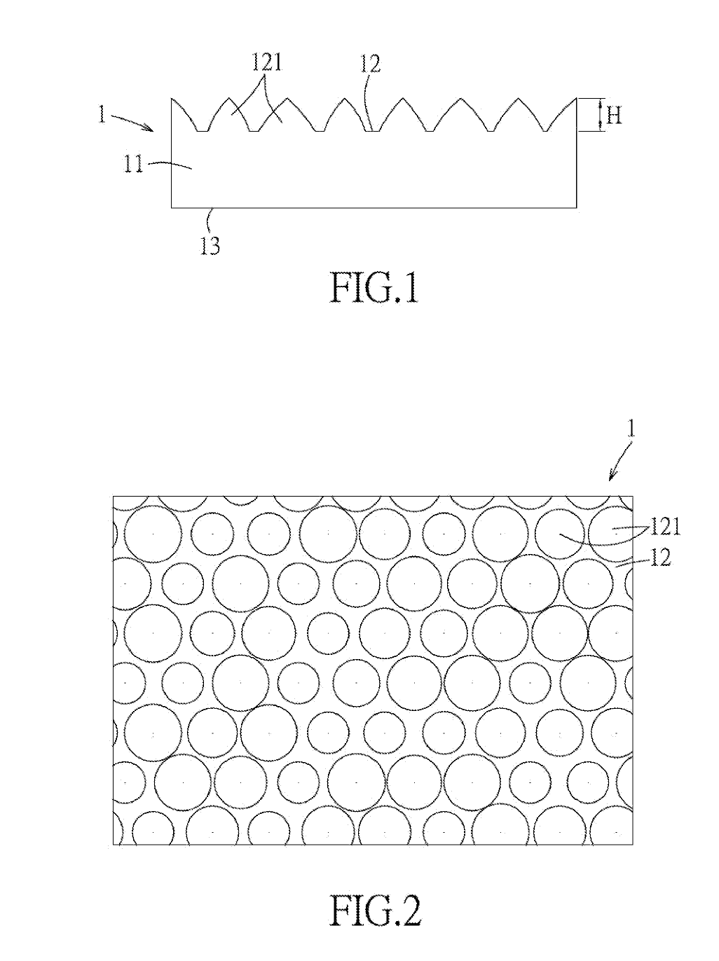

Referring to FIGS. 1 to 3, the preferred embodiment of an epitaxial substrate 1 according to the present invention includes a main body 11 having a first surface 12 and a second surface 13 opposite to the first surface 12, and a plurality of protrusions 121 formed on the first surface 12 of the main body 11 and spaced apart from one another. Each of the protrusions 121 has a dimension different from at least an adjacent one of the protrusions 121. The size of each of the protrusions 121 is in nano-scale order or micro-scale order. The main body 11 and the protrusions 121 are independently made of a material selected from the group consisting of aluminum oxide (Al₂O₃), silicon carbide (SiC), gallium nitride (GaN), silicon (Si), and combinations thereof.

The protrusions 121 respectively have symmetrical centers. In this embodiment, the symmetrical centers of the protrusions 121 are equidistantly arranged, that is, every group of three of the protrusions 121 that are adjacent to one another are arranged such that the symmetrical centers thereof are respectively at three vertices of an equilateral triangle. More specifically, six of the protrusions 121 that are adjacent to a common one of the protrusions 121 are arranged such that the symmetrical centers thereof are respectively at six vertices of a regular hexagon.

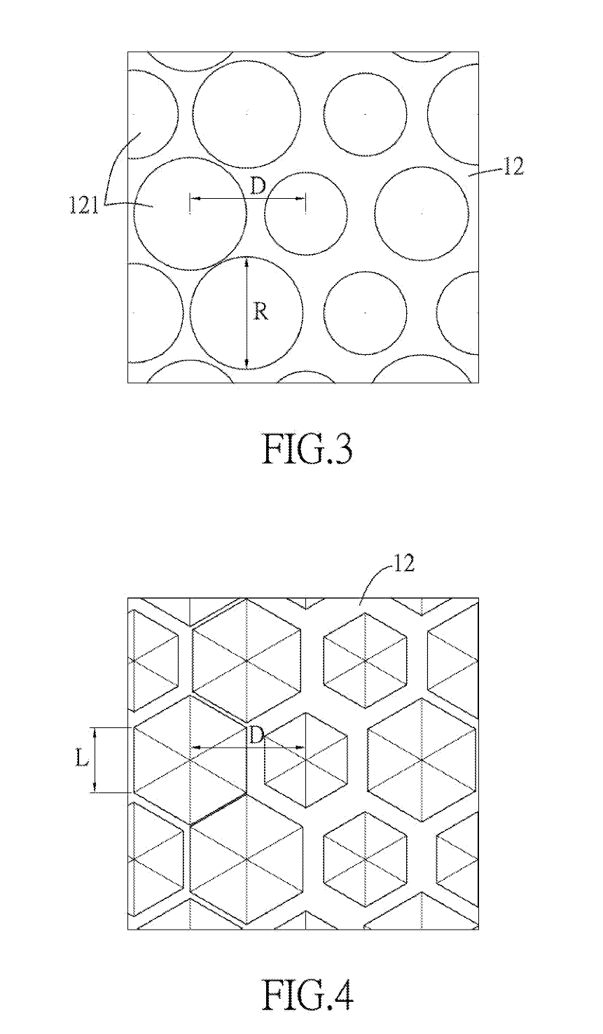

Each of the protrusions 121 is tapered from the first surface 12 of the main body 11. For example, as shown in FIG. 3, each of the protrusions 121 has a circular cone shape, and has a circular base formed on the first surface 12 of the main body 11. The circular base has a diameter (R) that ranges from 0.2 to 4.8 micrometers. Each of the protrusions 121 has a height (H) from the first surface 12 of the main body 11 ranging from 0.2 to 2 micrometers (see FIG. 1). A distance (D) between two adjacent ones of the symmetrical centers ranges from 0.5 to 5 micrometers. In this embodiment, the major difference between adjacent ones of the protrusions 121 is the diameter (R) of the circular base.

It should be noted that variation in the structure of the protrusions 121 is permitted. For example, each of the protrusions 121 may have a polygonal cone shape and has a polygonal base formed on the first surface 12 of the main body 11. The polygonal base has a plurality of sides, and each of which has a length ranging from 0.1 to 2.4 micrometers. FIG. 4 shows a variation of the preferred embodiment of an epitaxial substrate 1 according to this invention, in which each of the protrusions 121 has a hexagonal cone shape and has a hexagonal base formed on the first surface 12 of the main body 11. The hexagonal base has six sides, and each of which has a length (L) ranging from 0.1 to 2.4 micrometers. Each of the protrusions 121 has a height (H) from the first surface 12 of the main body 11 ranging from 0.2 to 2 micrometers. A distance (D) between two adjacent ones of the symmetrical centers ranges from 0.5 to 5 micrometers.

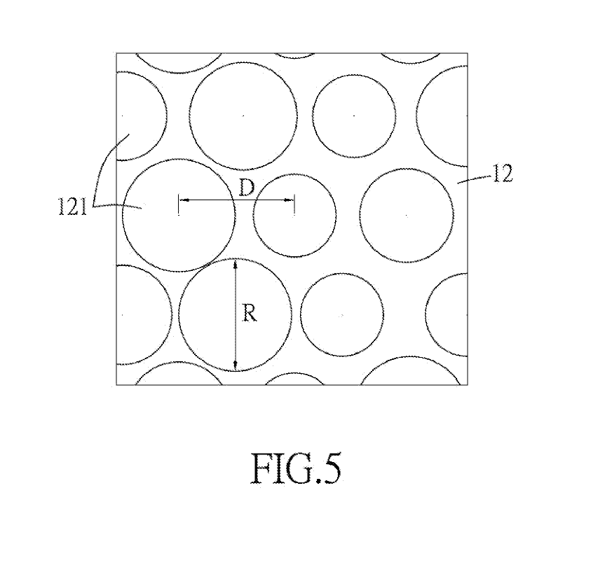

FIG. 5 shows another variation of the preferred embodiment of the epitaxial substrate 1 according to this invention. In this variation, some of the symmetrical centers are inequidistantly arranged. Thus, six of the protrusions 121 that are adjacent to a common one of the protrusions 121 are arranged such that the symmetrical centers thereof are respectively and substantially at six vertices of an irregular hexagon.

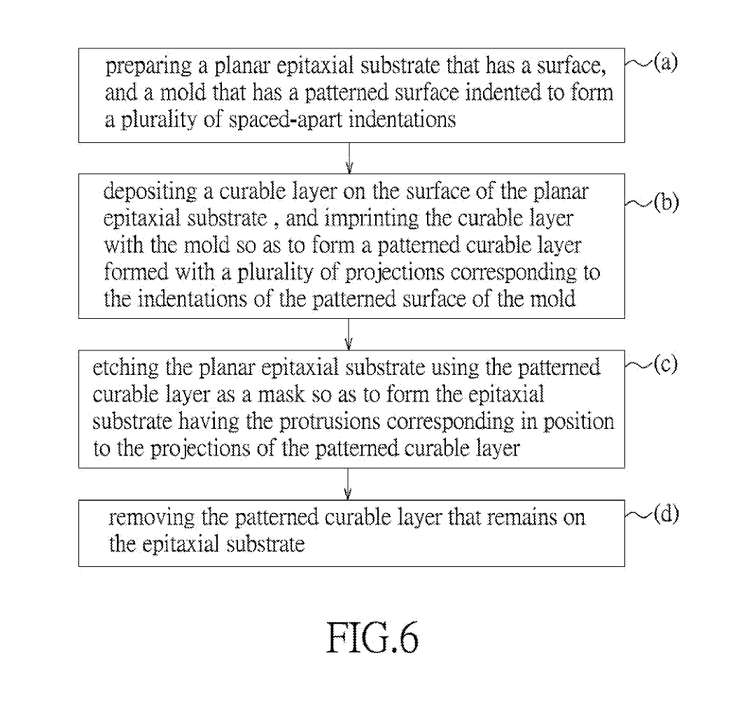

Referring to FIGS. 1, 2, 6 and 7(A) to 7(E), a method for producing the aforesaid epitaxial substrate 1 includes the following steps of:

(a) preparing a planar epitaxial substrate 1′ that has a surface 14′, and a mold 2 that has a patterned surface indented to form a plurality of spaced-apart indentations 22;

(b) depositing a curable layer 3′ on the surface 14′ of the planar epitaxial substrate 1′, and imprinting the curable layer 3′ with the mold 2 so as to form a patterned curable layer 3 formed with a plurality of projections 31 corresponding to the indentations 22 of the patterned surface 21 of the mold 2;

(c) etching the planar epitaxial substrate 1′ using the patterned curable layer 3 as a mask so as to form the epitaxial substrate 1 having the protrusions 121 corresponding in position to the projections 31 of the patterned curable layer 3; and

(d) removing the patterned curable layer 3 that remains on the epitaxial substrate 1.

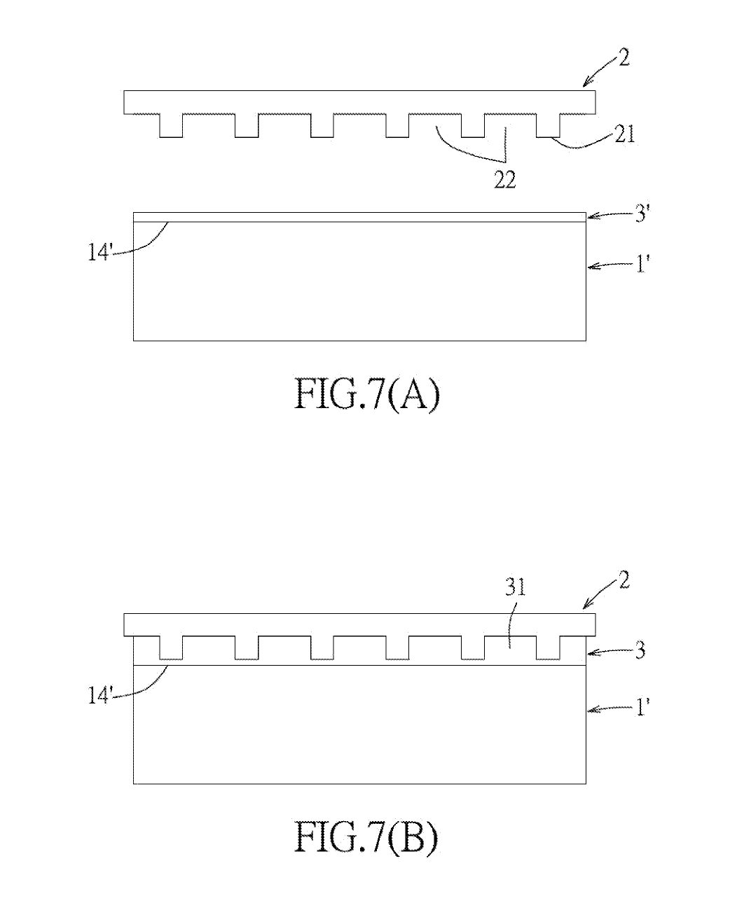

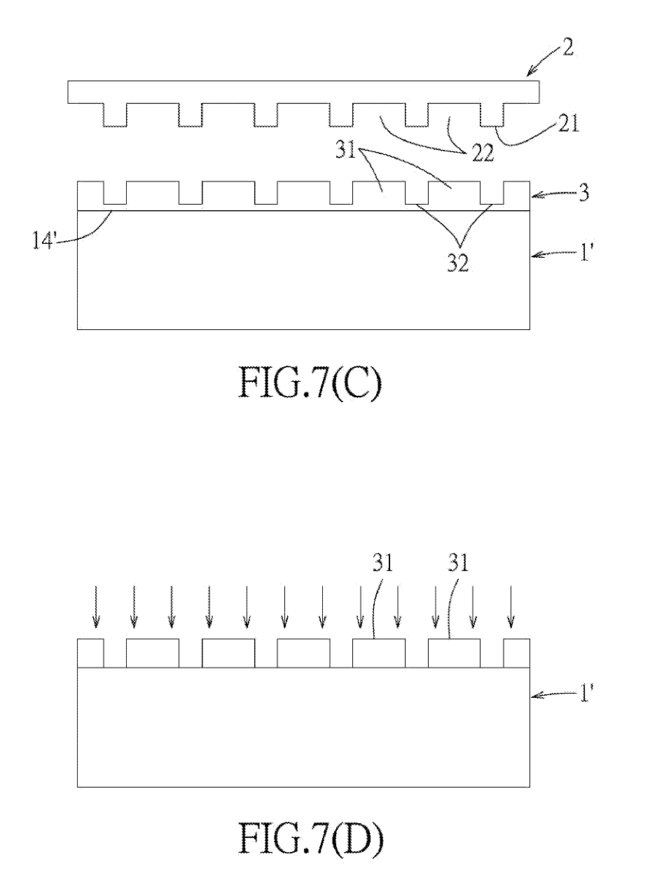

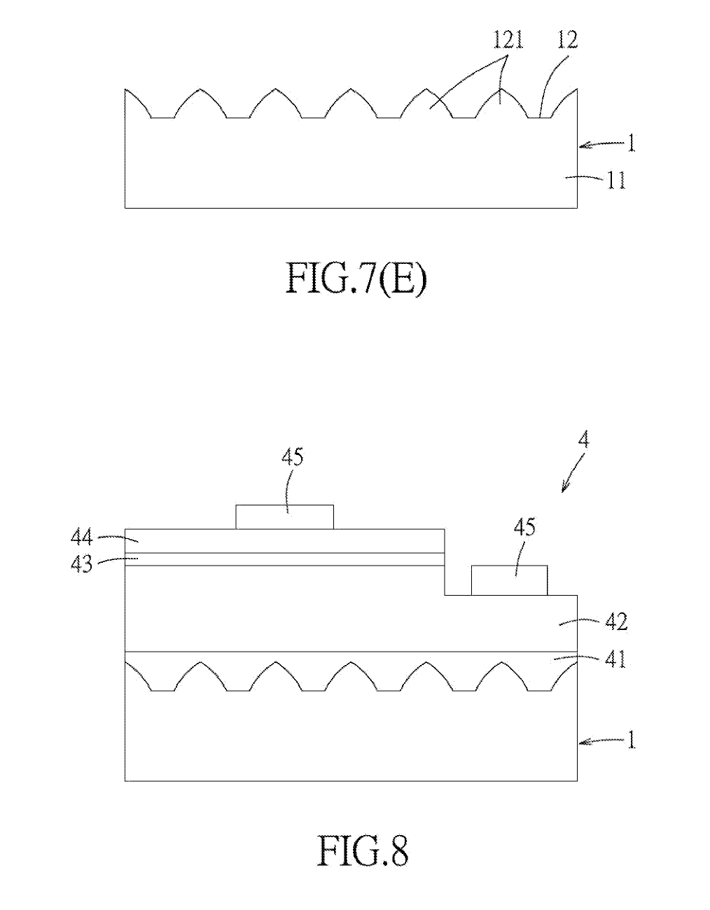

Referring to FIGS. 7(A) to 7(C), in steps (a) and (b), the planar epitaxial substrate 1′ is a sapphire substrate. In this embodiment, the planar epitaxial substrate 1′ is a sapphire substrate made of aluminum oxide (Al₂O₃). The indentations 22 of the patterned surface 21 of the mold 2 are equidistantly arranged. The curable layer 3′ is made of a photo-curing material or a thermal-curing material. In this embodiment, the curable layer 3′ is made of a photo-curable photoresist material. In step (b), the curable layer 3′ is coated on the surface 14′ of the planar epitaxial substrate 1′ and is then soft baked to a semi-solid state (see FIG. 7 (A)), followed by imprinting the curable layer 3′ with the mold 2 and photo-curing the curable layer 3′ with ultra-violet light so as to form the patterned curable layer 3 formed with the projections 31 (see FIG. 7 (B)). The mold 2 is then removed from the patterned curable layer 3 (see FIG. 7(C)).

The imprinting technology allows the patterned etching mask to be produced in a one-step process. Furthermore, the protrusions 121 thus obtained can be formed with various dimensions.

Referring to FIGS. 7(D) and 7(E), in steps (c) and (d), during the etching procedure, the projections 31 of the pattered curable layer 3 can temporarily prevent the planer epitaxial substrate 1′ thereunder from being etched, and the portions of the planer epitaxial substrate 1′ under recesses 32 among the projections 31 would be etched so that the planer epitaxial substrate 1′ under the projections 31 eventually forms the protrusions 121.

In this embodiment, step (c) is conducted by dry-etching. The etchant is, e.g., a chlorine-containing etching gas. By virtue of adjusting bias voltage, gas flow, reaction time and other processing parameters during the etching procedure, configuration of the protrusions 121 can be controlled to a desired shape, such as a circular cone shape or a polygonal cone shape.

After step (d), the epitaxial substrate 1 is cleaned. It should be noted that the material of the curable layer 3′ and the parameters of the etching procedure can be adjusted based on actual requirements. Therefore, it should be understood that the abovementioned description is only illustrative and should not be taken as a limitation for this invention.

Referring to FIG. 8, the preferred embodiment of a light emitting diode 4 according to the present invention includes the aforesaid epitaxial substrate 1, a buffer layer 41, a first-type semiconductor layer 42, a semiconductor light emitting layer 43, a second-type semiconductor layer 44 and two electrodes 45. The buffer layer 41 is deposited on the main body 11 and the protrusions 121 of the epitaxial substrate 1. The first-type semiconductor layer 42 is deposited on the buffer layer 41 opposite to the epitaxial substrate 1.

The semiconductor light emitting layer 43 is deposited on the first-type semiconductor layer 42 opposite to the buffer layer 41. The second-type semiconductor layer 44 is deposited on the semiconductor light emitting layer 43 opposite to the first-type semiconductor layer 42, and has an electrical property opposite to that of the first-type semiconductor layer 42. The electrodes 45 are adapted to be electrically connected to an external power source, and are connected electrically and respectively to the first-type semiconductor layer 42 and the second-type semiconductor layer 44.

In this embodiment, the light emitting diode 4 is a blue light emitting diode. The buffer layer 41, the first-type semiconductor layer 42, the semiconductor light emitting layer 43 and the second-type semiconductor layer 44 are mainly made of a gallium nitride-based material. The first-type semiconductor layer 42 is made of an n-type gallium nitride-based material. The semiconductor light emitting layer 43 includes a multiple quantum well (MQW) structure (not shown) that is composed of a plurality of indium gallium nitride (InGaN) layers with different indium (In) content. The semiconductor light emitting layer 43 is the main light emitting region of the light emitting diode 4. The second-type semiconductor layer 44 is made of a p-type gallium nitride-based material. The electrodes 45 are mainly made of metal. It should be understood that the abovementioned description is only illustrative and should not be taken as a limitation for the light emitting diode 4 of this invention.

Compared to a light emitting diode that includes a conventional epitaxial substrate having the protrusions with the same dimensions, the light emitting diode 4 including the epitaxial substrate 1 according to the present invention shows an increase of 2% in brightness under the same conditions, e.g., the same structure of the light emitting diode, the same electrodes, the same external power source, and the same fill factor (i.e., the total area of the base surfaces of the protrusions 121 per unit area of the first surface 12 of the epitaxial substrate 1).

To sum up, by virtue of the imprinting technology and the etching technology, the epitaxial substrate 1 of this invention can be formed with the protrusions 121 having various dimensions in nano-scale and/or micro-scale order. The brightness of the light emitting diode 4 having the epitaxial substrate 1 according to the present invention can be improved.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. An epitaxial substrate comprising:
a main body having a surface; and
a plurality of protrusions formed on said surface of said main body and spaced apart from one another, each of said protrusions having a dimension different from at least an adjacent one of said protrusions.

2. The epitaxial substrate as claimed in claim 1, wherein said protrusions respectively have symmetrical centers, said symmetrical centers being equidistantly arranged.

3. The epitaxial substrate as claimed in claim 1, wherein said protrusions respectively have symmetrical centers, some of said symmetrical centers being inequidistantly arranged.

4. The epitaxial substrate as claimed in claim 1, wherein each of said protrusions has a circular cone shape.

5. The epitaxial substrate as claimed in claim 1, wherein each of said protrusions has a polygonal cone shape.

6. The epitaxial substrate as claimed in claim 4, wherein each of said protrusions has a circular base that is formed on said surface of said main body and that has a diameter ranging from 0.2 to 4.8 micrometers, each of said protrusions having a height from said surface of said main body ranging from 0.2 to 2 micrometers, said protrusions respectively having symmetrical centers, a distance between two adjacent ones of the symmetrical centers ranging from 0.5 to 5 micrometers.

7. The epitaxial substrate as claimed in claim 5, wherein each of said protrusions has a polygonal base that is formed on said surface of said main body, said polygonal base having a plurality of sides, each of which having a length that ranges from 0.1 to 2.4 micrometers, each of said protrusions having a height from said surface of said main body ranging from 0.2 to 2 micrometers, said protrusions respectively having symmetrical centers, a distance between two adjacent ones of the symmetrical centers ranging from 0.5 to 5 micrometers.

8. The epitaxial substrate as claimed in claim 7, wherein each of said protrusions has a hexagonal base.

9. The epitaxial substrate as claimed in claim 1, wherein each of said epitaxial substrate is tapered from said surface of said main body

10. The epitaxial substrate as claimed in claim 1, wherein said main body and said protrusions are independently made of a material selected from the group consisting of aluminum oxide, silicon carbide, gallium nitride, silicon, and combinations thereof.

11. The epitaxial substrate as claimed in claim 3, wherein six of said protrusions that are adjacent to a common one of said protrusions are arranged such that symmetrical centers thereof are respectively at six vertices of a hexagon.

12. A method for producing the epitaxial substrate of claim 1, comprising the steps of:
(a) preparing a planar epitaxial substrate that has a surface, and a mold that has a patterned surface indented to form a plurality of spaced-apart indentations;
(b)depositing a curable layer on the surface of the planar epitaxial substrate, and imprinting the curable layer with the mold so as to form a patterned curable layer formed with a plurality of projections corresponding to the indentations of the surface of the mold; and
(c) etching the planar epitaxial substrate using the patterned curable layer as a mask so as to form the epitaxial substrate having the protrusions corresponding in position to the projections of the patterned curable layer.

13. The method as claimed in claim 12, wherein the curable layer is made of a photo-curing material or a thermal-curing material.

14. The method as claimed in claim 12, step (c) is conducted by dry etching.

15. The method as claimed in claim 12, further comprising, after step (c), a step (d) of removing the patterned curable layer that remains on the epitaxial substrate.

16. A light emitting diode comprising:
an epitaxial substrate as claimed in claim 1;
a buffer layer deposited on said main body and said protrusions of said epitaxial substrate;
a first-type semiconductor layer deposited on said buffer layer opposite to said epitaxial substrate;
a semiconductor light emitting layer deposited on said first-type semiconductor layer opposite to said buffer layer;
a second-type semiconductor layer deposited on said semiconductor light emitting layer opposite to said first-type semiconductor layer, and having an electrical property opposite to that of said first-type semiconductor layer; and
two electrodes adapted to be electrically connected an external power source and connected electrically and respectively to said first-type semiconductor layer and said second-type semiconductor layer.
